(19) United States
(12) Patent Application Publication
(10) Pub. No.: US 2025/0268109 A1
(43) Pub. Date: Aug. 21, 2025

(54) MAGNETORESISTANCE EFFECT ELEMENT, MAGNETIC SENSOR, AND CAMERA MODULE

(71) Applicant: TDK Corporation, Tokyo (JP)

(72) Inventor: Takafumi KOBAYASHI, Tokyo (JP)

(21) Appl. No.: 19/035,323

(22) Filed: Jan. 23, 2025

(30) Foreign Application Priority Data
Feb. 21, 2024 (JP) 2024-024598

(51) Int. Cl. H10N 50/10; G01R 33/00; G01R 33/09

(52) U.S. Cl. CPC H10N 50/10; G01R 33/0052; G01R 33/093; G01R 33/098

(57) ABSTRACT

The magnetoresistance effect element comprises a magnetization free layer in which magnetization direction is caused to rotate by an external magnetic field, a magnetization fixed layer in which magnetization direction is fixed in a first direction, a nonmagnetic spacer layer located between the magnetization free layer and the magnetization fixed layer, and two magnet layers that sandwich the magnetization free layer in a second direction different from the first direction. When viewed from a third direction that is perpendicular to the first direction and the second direction, the magnetization free layer includes an end portion that faces either of the two magnet layers, and two linear sides that are connected to the end portion and that extend in different directions from each other. The two linear sides are inclined with respect to the second direction.

### FIELD

This application claims the benefit of Japanese Priority Patent Application No. JP 2024-024598 filed on Feb. 21, 2024, the entire contents of which are incorporated herein by reference.

The present disclosure relates to a magnetoresistance effect element, a magnetic sensor, and a camera module including the same.

### BACKGROUND

A magnetoresistance effect element used in a magnetic sensor or the like comprises a magnetization free layer in which magnetization direction is caused to rotate by an external magnetic field, a magnetization fixed layer in which magnetization direction is fixed, and a spacer layer that is located between the magnetization free layer and the magnetization fixed layer and that has a magnetoresistance effect. To stabilize the magnetization direction of the magnetization free layer in a state in which no external magnetic field is applied, a magnet layer that applies a bias magnetic field to the magnetization free layer may be provided. JP 2019-169613 A discloses a magnetoresistance effect element that has a magnet layer surrounding a magnetization free layer.

### SUMMARY

It is known that when the magnetization free layer has a rectangular shape, the magnetization direction near the boundary between the magnetization free layer and the magnet layer is inclined with respect to other parts of the magnetization free layer due to the influence of a demagnetizing field. The magnetization free layer described in JP 2019-169613 A has an elliptical shape that reduces the influence of the demagnetizing field and therefore reduces output hysteresis. However, since the magnet layer surrounds the magnetization free layer, the magnetic flux tends to bypass the magnetization free layer and thus complicates the application of a bias magnetic field to the magnetization free layer.

The magnetoresistance effect element of the present disclosure comprises a magnetization free layer in which magnetization direction is rotated by an external magnetic field, a magnetization fixed layer in which magnetization direction is fixed in a first direction, a nonmagnetic spacer layer that is located between the magnetization free layer and the magnetization fixed layer, and two magnet layers that sandwich the magnetization free layer in a second direction different from the first direction. When viewed from a third direction that is perpendicular to the first direction and the second direction, the magnetization free layer includes an end portion that faces either of the two magnet layers, and two linear sides that are connected to the end portion and that extend in different directions from each other. The two linear sides are inclined with respect to the second direction.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic configuration diagram of a magnetoresistance effect element according to a first embodiment of the present disclosure;

FIG. 2 is a plan view of a magnetization free layer and magnet layers shown in FIG. 1;

FIGS. 3A to 3G are diagrams illustrating hysteresis in Comparative Example 1;

FIGS. 4A and 4B are diagrams illustrating hysteresis in Comparative Example 2;

FIGS. 5A to 5D are conceptual diagrams showing the relationship between magnet layers and magnetic flux;

FIGS. 6A and 6B are diagrams showing a calculation model used in a simulation of hysteresis;

FIGS. 7A and 7B are graphs showing simulation results of hysteresis;

FIG. 8 is a schematic configuration diagram of a magnetoresistance effect element according to a modification of the first embodiment;

FIG. 9 is a plan view of a magnetization free layer and magnet layers of a magnetic sensor according to a second embodiment of the present disclosure;

FIG. 10 is a schematic configuration diagram of a magnetic sensor according to a third embodiment of the present disclosure; and

FIG. 11 is a schematic configuration diagram of a camera module according to a fourth embodiment of the present disclosure.

### DETAILED DESCRIPTION

In the following explanation, some example embodiments and modifications of the technology are described in detail with reference to the accompanying drawings. Note that the following description is directed to illustrative examples of the disclosure and not to be construed as limiting the technology. Factors including, without limitation, numerical values, shapes, materials, components, positions of the components, and the manner in which components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

An object of the present disclosure is to provide a magnetoresistance effect element capable of both applying a large bias magnetic field to a magnetization free layer and reducing hysteresis.

Embodiments of a magnetoresistance effect element, a magnetic sensor, and a camera module according to the present disclosure will be described with reference to the drawings. In the following description and drawings, first direction X is a magnetic sensing direction of magnetoresistance effect element 1 and coincides with the magnetization direction of the magnetization fixed layer. Second direction Y is a direction in which two magnet layers (hereinafter referred to as first magnet layer 21 and second magnet layer 22) are arranged. Third direction Z coincides with the stacking direction of laminated body 4 to be described. First direction X and second direction Y are parallel to element mounting surface 2A of substrate 2. First direction X, second direction Y, and third direction Z are perpendicular to one another. Second direction Y does not have to be perpendicular to first direction X, but may be any direction different from first direction X.

### First Embodiment

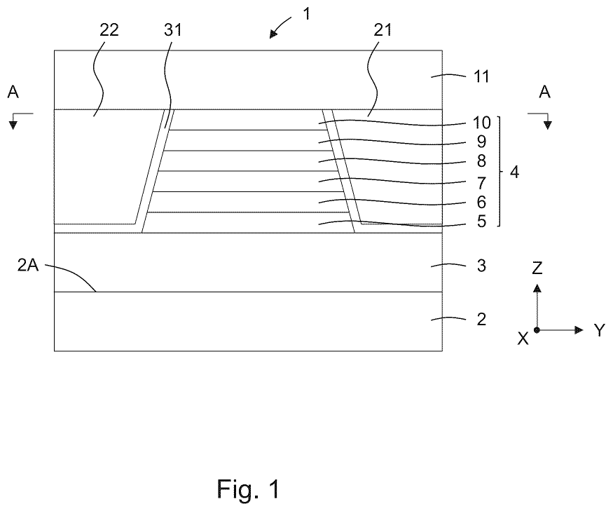

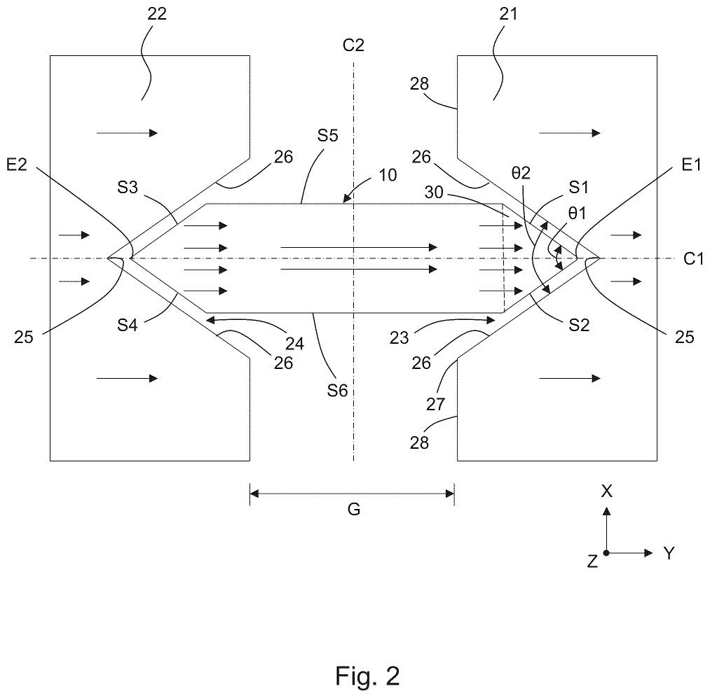

FIG. 1 is a cross-sectional view showing a schematic configuration of magnetoresistance effect element 1 according to the first embodiment, and FIG. 2 is a plan view of magnetization free layer 10 and magnet layers taken along line AA in FIG. 1. With reference to FIG. 1, magnetoresistance effect element 1 includes substrate 2, lower electrode layer 3, laminated body 4, and upper electrode layer 11. Laminated body 4 comprises antiferromagnetic layer 5, outer magnetization fixed layer 6, nonmagnetic intermediate layer 7, inner magnetization fixed layer 8, spacer layer 9, and magnetization free layer 10, and these layers 5 to 10 are stacked in the above order in third direction Z from lower electrode layer 3 to upper electrode layer 11. A sense current flows in laminated body 4 in third direction Z by including lower electrode layer 3 and upper electrode layer 11.

Magnetization free layer 10 is a magnetic layer in which magnetization direction is caused to rotate by an external magnetic field and can be made of, for example, NiFe. Spacer layer 9 is a nonmagnetic layer located between magnetization free layer 10 and magnetization fixed layer 8. Spacer layer 9 can be made of a nonmagnetic insulator such as Al₂O₃ or MgO, or a nonmagnetic conductor such as Cu. When spacer layer 9 is a nonmagnetic insulator, magnetoresistance effect element 1 functions as a tunneling magnetoresistance effect (TMR) element, and when spacer layer 9 is a nonmagnetic conductor, magnetoresistance effect element 1 functions as a giant magnetoresistance effect (GMR) element. A TMR element has a larger MR change rate than a GMR element and can increase the output voltage of magnetic sensor 100, an effect that will be described later.

Inner magnetization fixed layer 8 is a ferromagnetic layer that is sandwiched between outer magnetization fixed layer 6 and spacer layer 9. Inner magnetization fixed layer 8 is antiferromagnetically-coupled to outer magnetization fixed layer 6 via nonmagnetic intermediate layer 7 that is made of, for example, Ru or Rh. Outer magnetization fixed layer 6 is a ferromagnetic layer that is exchange-coupled with antiferromagnetic layer 5. Antiferromagnetic layer 5 can be made of PtMn, IrMn, NiMn, or the like. The magnetization directions of inner magnetization fixed layer 8 and outer magnetization fixed layer 6 are fixed and are antiparallel to each other. In this specification, inner magnetization fixed layer 8 may be simply referred to as magnetization fixed layer 8.

Magnetoresistance effect element 1 includes first and second magnet layers 21 and 22 that sandwich magnetization free layer 10 in second direction Y and that apply a bias magnetic field to magnetization free layer 10. First magnet layer 21 and second magnet layer 22 face each other in second direction Y via a gap G therebetween. First magnet layer 21 and second magnet layer 22 have the same configuration and shape, and are symmetrical with respect to second axis C2 to be described. The magnetization direction of magnetization free layer 10 may be oriented in second direction Y when an external magnetic field to be detected is not applied (hereinafter, referred to as a zero magnetic field). First and second magnet layers 21 and 22 are magnetized in second direction Y and in the same direction (to the right in FIGS. 1 and 2) and apply a bias magnetic field generally in second direction Y to magnetization free layer 10. First and second magnet layers 21 and 22 are made of a hard magnetic material such as CoPt or CoCrPt. As shown in FIG. 1, first and second magnet layers 21 and 22 are provided over almost the entire area of laminated body 4 in third direction Z but may only be provided on at least the sides of magnetization free layer 10 in second direction Y. Insulating layer 31 made of Al₂O₃ or the like is provided between laminated body 4 and first and second magnet layers 21 and 22. Insulating layer 31 prevents the sense current flowing through laminated body 4 from leaking to first and second magnet layers 21 and 22 and prevents, in particular, a short circuit between magnetization free layer 10 and magnetization fixed layer 8. Insulating layer 31 is omitted in FIG. 2.

Magnetoresistance effect element 1 is formed longer and narrower in second direction Y than in first direction X. Therefore, as shown in FIG. 2, when viewed from third direction Z, magnetization free layer 10 is longer and narrower in second direction Y than in first direction X, and the magnetization direction is easily oriented in second direction Y due to the shape anisotropy effect. As described above, a bias magnetic field is applied to magnetization free layer 10 in second direction Y by first and second magnet layers 21 and 22. For the above reasons, magnetization free layer 10 is magnetized substantially in second direction Y in a zero-magnetic field state. In contrast, magnetization fixed layer 8 is magnetized generally in first direction X. When an external magnetic field is applied in a first direction X, which is the magneto-sensitive direction, the magnetization direction of magnetization free layer 10 as seen in FIG. 2 rotates clockwise or counterclockwise depending on the strength of the external magnetic field. This rotation changes the relative angle between the magnetization direction of magnetization fixed layer 8 and the magnetization direction of magnetization free layer 10, and the electrical resistance of magnetoresistance element 1 to the sense current changes. Based on this change in electrical resistance, magnetoresistance effect element 1 detects the strength of an external magnetic field in the sensing direction.

Next, the configurations of magnetization free layer 10 and first and second magnet layers 21 and 22 will be described in more detail with reference to FIG. 2. When viewed from third direction Z, magnetization free layer 10 includes: two end portions hereinafter referred to as first end portion E1 and second end portion E2 that face first and second magnet layers 21 and 22, respectively; first axis C1; and second axis C2. First axis C1 passes through first and second end portions E1 and E2 and is parallel to second direction Y. Second axis C2 passes through a point on first axis C1 equidistant from first end E1 and second end E2 and is perpendicular to first axis C1. First axis C1 coincides with the central axis of magnetization free layer 10 in second direction Y. Magnetization free layer 10 is symmetrical with respect to first axis C1 and second axis C2.

When viewed from third direction Z, magnetization free layer 10 is generally hexagonal in shape and includes: two linear sides (hereinafter referred to as first side S1 and second side S2) that are connected to first end portion E1 and that extend in different directions from each other; two linear sides (hereinafter referred to as third side S3 and fourth side S4) that are connected to second end portion E2 and that extend in different directions from each other; linear fifth side S5 that connects first side S1 and third side S3; and linear sixth side S6 that connects second side S2 and fourth side S4.

With respect to first axis C1, second side S2, fourth side S4, and sixth side S6 are symmetrical to first side S1, third side S3, and fifth side S5, respectively. Third side S3, fourth side S4 and second end portion E2 are symmetrical to first side S1, second side S2 and first end portion E1 with respect to second axis C2. First side S1, third side S3, and fifth side S5 extend on one side of first axis C1 in first direction X. In contrast, second side S2, fourth side S4, and sixth side S6 extend on the other side of first axis C1 in first direction X. In other words, first side S1 and second side S2, that are connected to first end portion E1 extend toward opposite sides of first axis C1 in first direction X, and third side S3 and fourth side S4 that are connected to second end portion E2 also extend toward opposite sides of first axis C1 in first direction X. First to fourth sides S1 to S4 are inclined with respect to first direction X and second direction Y. Fifth side S5 and sixth side S6 are parallel to second direction Y but may also be curved, for example, in first direction X. Since the shape of the first end portion E1 side and the shape of the second end E2 side of magnetization free layer 10 are the same, only the shape of first end portion E1 side will be described below.

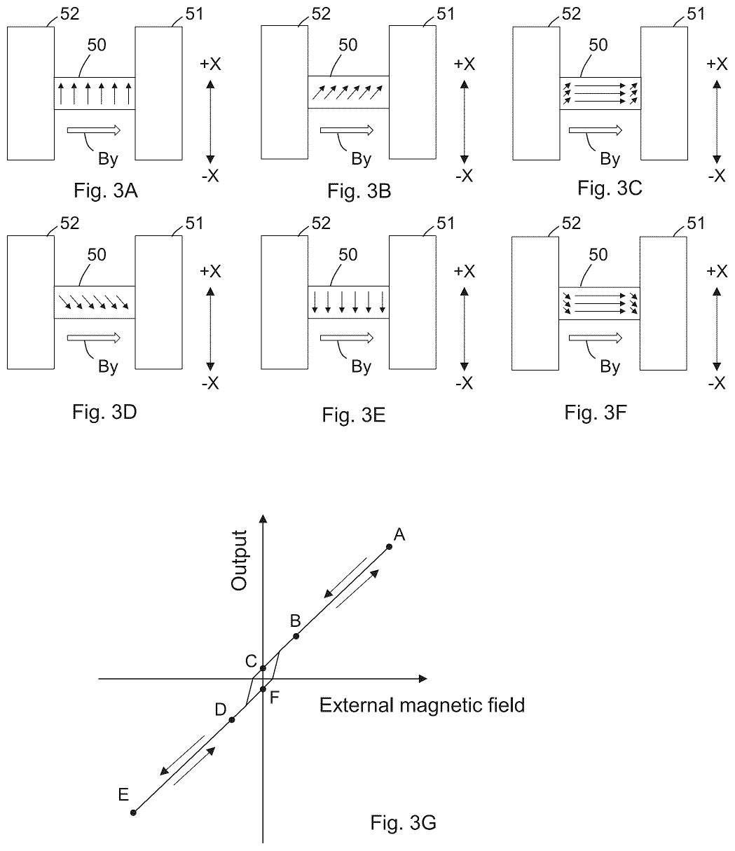

Providing first end portion E1 and second end portion E2 in magnetization free layer 10 in this manner enables a reduction of the hysteresis of the output of magnetoresistance element 1. FIGS. 3A to 3F show with arrows the magnetization direction of magnetization free layer 50 of Comparative Example 1 when an external magnetic field is applied, and FIG. 3G shows the states of FIGS. 3A to 3F as a relationship between the external magnetic field and the output. Magnetization free layer 50 of Comparative Example 1 is rectangular, and first and second magnet layers 51 and 52 in the first embodiment are also rectangular. The positive direction in first direction X is defined as the +X-direction, and the negative direction is defined as the −X-direction. An external magnetic field was applied so as to change from the +X-direction to the −X-direction, and then to change from the −X-direction to the +X-direction. The bias magnetic field By is oriented to the right in FIGS. 3A to 3F.

As shown in FIG. 3A, when a large external magnetic field is applied in the +X-direction, the magnetization direction of magnetization free layer 50 is generally oriented in the +X-direction (point A in FIG. 3G). As shown in FIG. 3B, when the strength of the external magnetic field in the +X-direction decreases, the contribution of the bias magnetic field increases, and the magnetization direction of magnetization free layer 50 rotates clockwise, but the magnetization direction of magnetization free layer 50 generally points in the same direction (point B in FIG. 3G). As shown in FIG. 3C, when the external magnetic field strength in the X-direction becomes zero, the magnetization direction in the part of magnetization free layer 50 remote from first and second magnet layers 51 and 52 is oriented in the same direction as the bias magnetic field, but the influence of the demagnetizing field becomes relatively stronger at the ends that are close to first and second magnet layers 51 and 52. Since the demagnetizing field acts to prevent the rotation of the magnetic field direction of magnetization free layer 50, the magnetization direction at the end surface of magnetization free layer 50 tilts upward. As a result, the magnetization direction of magnetization free layer 50 is directed slightly upward on average (point C in FIG. 3G). As shown in FIG. 3D, when an external magnetic field is applied in the −X-direction, the magnetization direction of magnetization free layer 50 rotates clockwise but the magnetization direction of magnetization free layer 50 generally faces the same direction (point D in FIG. 3G). As shown in FIG. 3E, when a large external magnetic field is applied in the −X-direction, the magnetization direction of magnetization free layer 50 is generally oriented in the −X-direction (point E in FIG. 3G).

When the external magnetic field is changed from the −X-direction to the +X-direction, the state returns from FIG. 3E to FIG. 3D. However, as shown in FIG. 3F, when the strength of the external magnetic field in the X-direction becomes zero, the magnetization direction at the end surfaces of magnetization free layer 50 tilts downward due to the influence of the demagnetizing field (point F in FIG. 3G). As a result, the magnetization direction of magnetization free layer 50 is directed slightly downward on average. When an external magnetic field is applied in the +X-direction, the state returns to that of FIG. 3A via the state of FIG. 3B. The magnetization direction of magnetization free layer 50 is determined so as to minimize the sum of the magneto-static energy and the exchange energy, and the sums of the magneto-static energy and the exchange energy at points C and F are the same. Therefore, in a zero magnetic field, the magnetization state of magnetization free layer 50 differs when the magnetic field changes from the +X-direction to the −X-direction and when the magnetic field changes from the −X direction to the +X-direction. As a result, the output of magnetoresistance effect element 1 can selectively assume two values in a zero magnetic field, resulting in hysteresis.

In the first embodiment, in contrast, since first end portion E1 is provided in magnetization free layer 10 as shown in FIG. 2, the influence of the demagnetizing field is reduced and realizes a reduction of hysteresis. Since a sharp edge reduces hysteresis, first end portion E1 is an edge but may be somewhat rounded. For a similar reason, hysteresis is also reduced because the tip region of magnetization free layer 10 in the Y-direction has an elongated shape. Therefore, angle θ1 between first side S1 and second side S2 is greater than or equal to 20 degrees and less than or equal to 120 degrees, and angle θ1 may be greater than or equal to 20 degrees and less than or equal to 100 degrees.

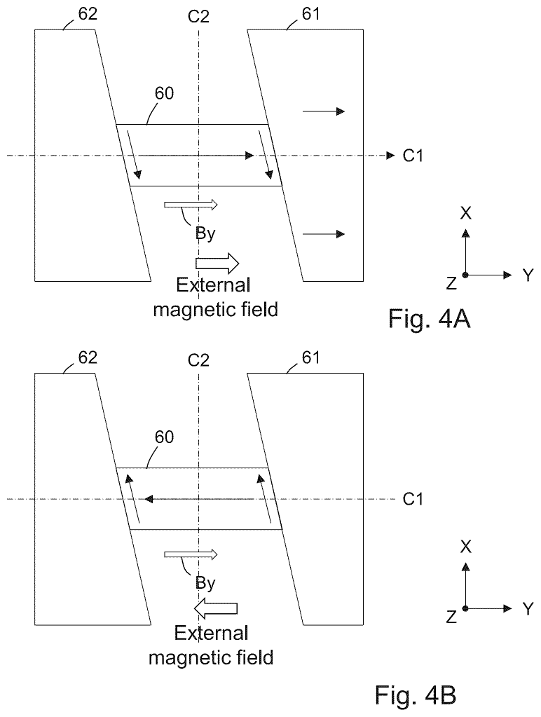

FIGS. 4A and 4B are plan views of magnetization free layer 60 and first and second magnet layers 61 and 62 of the magnetoresistance element of Comparative Example 2. When viewed from third direction Z, the sides of magnetization free layer 60 that face first and second magnet layers 61 and 62 are single straight lines inclined with respect to second axis C2 of magnetization free layer 60. Bias magnetic field By is directed toward the right. Compared to the first embodiment, Comparative Example 2 does not have first side S1 and second side S2 that extend in different directions on opposite sides of first axis C1. The surfaces of first and second magnet layers 61 and 62 that face magnetization free layer 10 are also inclined with respect to second axis C2 of magnetization free layer 10. As shown in FIG. 4A, when an external magnetic field is applied in the +Y-direction, the magnetization direction along the sides of magnetization free layer 60 that face first and second magnet layers 61 and 62 is downward. However, when the magnetization direction of magnetization free layer 60 is reversed as shown in FIG. 4B, the magnetization direction of the boundary portion is accordingly directed upward. This causes hysteresis in the output, and the reliability of the magnetoresistance effect element is consequently difficult to ensure.

On the other hand, in the first embodiment, first side S1 and second side S2 extend on both sides of first axis C1 and are inclined with respect to second direction Y, and the X-direction components of the magnetization along first side S1 and second side S2 therefore cancel each other out. For this reason, hysteresis can be largely reduced. In particular, when first side S1 and second side S2 are symmetrical with respect to first axis C1, the magnetic flux along first side S1 and second side S2 cancel each other out more effectively in the X direction, thereby enabling a significant reduction of hysteresis.

As shown in FIG. 2, first magnet layer 21 that faces first end portion E1 includes in its surface that faces second magnet layer 22 first recess 23 that accommodates first side S1 and second side S2 of magnetization free layer 10. Second magnet layer 22 that faces second end portion E2 includes in its surface that faces first magnet layer 21 second recess 24 on the surface that faces first magnet layer 21 that accommodates third side S3 and fourth side S4 of magnetization free layer 10. Since first magnet layer 21 and second magnet layer 22 have the same configuration and shape, only the configuration of first magnet layer 21 will be described below. When viewed from third direction Z, first recess 23 has a shape complementary to first and second sides S1 and S2. Specifically, when viewed from third direction Z, first recess 23 has innermost portion 25 that faces first end E1 in second direction Y, and two linear laterals 26 that are connected to innermost portion 25 and that face first and second sides S1 and S2, respectively, in second direction Y. Angle θ2 between laterals 26 may be the same as angle θ1 between first side S1 and second side S2. Innermost portion 25 is ideally the intersection of first side S1 and second side S2, but may also be somewhat rounded.

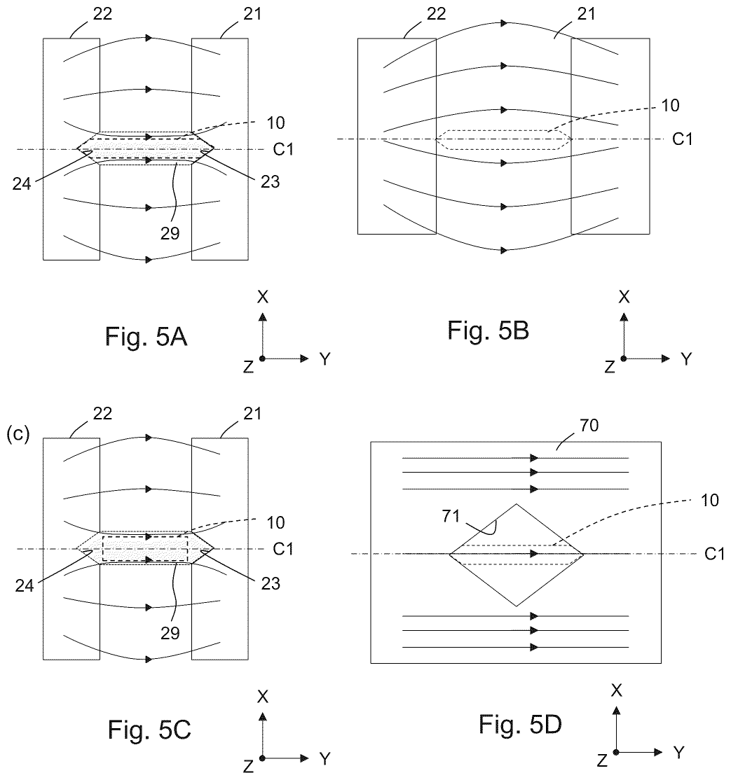

FIG. 5A schematically shows the magnetic flux flowing between first magnet layer 21 and second magnet layer 22 of this embodiment. Region 29 is a region between first recess 23 and second recess 24. Magnetization free layer 10 is indicated by dashed lines. By providing first recess 23 in first magnet layer 21 and providing second recess 24 in second magnet layer 22, the magnetic flux near first axis C1 bends slightly inward to approach first axis C1. Enabling a more uniform application of the magnetic field to magnetization free layer 10 in the Y-direction allows a further reduction of the hysteresis of the output of magnetoresistance effect element 1. The configuration shown in FIG. 5B is a modification of this embodiment. First and second magnet layers 21 and 22 are rectangular when viewed from third direction Z, and no recesses are provided. The magnetic flux near first axis C1 bends outward away from first axis C1. Compared to this embodiment, the bias magnetic field is less likely to be aligned in the Y-direction, but due to the effect of the shape of magnetization free layer 10, the hysteresis of the output of magnetoresistance effect element 1 can be reduced even in this configuration. The configuration shown in FIG. 5C is another modification of this embodiment. When viewed from third direction Z, first magnet layer 21 includes first recess 23, second magnet layer 22 includes second recess 24, but magnetization free layer 10 is rectangular. Since the bias magnetic field is generated in the same manner as in FIG. 5A, the hysteresis of the output of magnetoresistance effect element 1 can also be reduced in this configuration. FIG. 5D shows magnet layer 70 of Comparative Example 3. Diamond-shaped opening 71 is provided in the center, and magnetization free layer 10 of this embodiment is placed in diamond-shaped opening 71. Magnetic field is applied in approximately the Y-direction near first axis C1 but since the magnetic flux mainly flows along the sides of magnetization free layer 10, the bias magnetic field applied to magnetization free layer 10 is weak.

As can be understood from the above explanation, in order to effectively apply a magnetic field in the Y-direction to magnetization free layer 10, two independent magnet layers 21 and 22 on opposite sides of magnetization free layer 10 in the Y-direction may be provided. Furthermore, since magnetic flux that is relatively aligned in the Y-direction is generated in region 29 (see FIG. 5A) between first recess 23 and second recess 24, magnetization free layer 10 may be completely contained within region 29 in order to apply this magnetic flux to magnetization free layer 10. For this purpose, referring to FIG. 2, the dimension of opening 27 of first recess 23 in first direction X may be larger than the dimension of magnetization free layer 10 in first direction X in opening 27. Moreover, the surface of first magnet layer 21 in which opening 27 is provided may have surfaces 28 that face second magnet layer 22 on both sides of opening 27. In this embodiment, first recess 23 is larger than triangular end region 30 of magnetic free layer 10. Specifically, two linear laterals 26 are longer than first side S1 and second side S2, and first recess 23 accommodates a part of fifth side S5 and a part of sixth side S6. The same applies to second magnet layer 22.

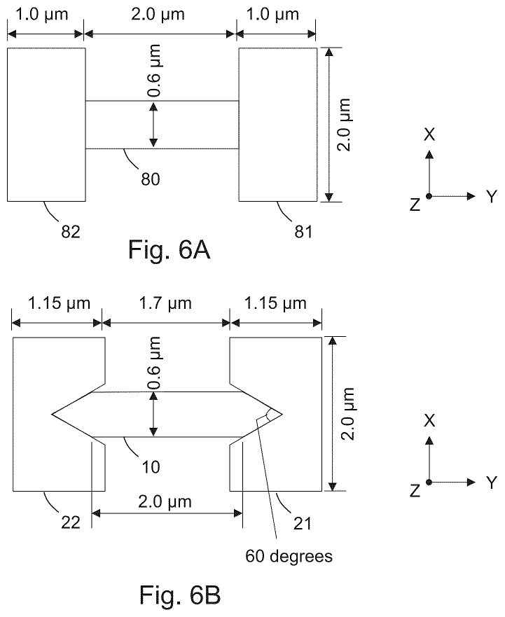

A simulation of hysteresis was performed to confirm the effect of this embodiment using the calculation model shown in FIGS. 6A and 6B. The simulation was performed using the simulation program “Mumax3” and was based on “Vansteenkiste et al., AIP Adv. 4, 107133 (2014)” and “Exl et al., J. Appl. Phys. 115, 17D118 (2014).” FIG. 6A is a plan view of magnetization free layer 80 and first and second magnet layers 81 and 82 of Comparative Example 4 viewed from third direction Z, and FIG. 6B is a plan view of magnetization free layer 10 and first and second magnet layers 21 and 22 of a working example viewed from third direction Z. The saturation magnetization of magnetization free layers 10 and 80 and magnet layers 21, 22, 81, and 82 was 1 T, the exchange stiffness coefficient of magnetization free layers 10 and 80 was 1×10⁻¹¹ J/m, and the film thickness of magnetization free layers 10 and 80 and magnet layers 21, 22, 81, and 82 was 10 nm. Magnet layers 21, 22, 81, and 82 were permanent magnet layers with a single magnetic domain structure, and the magnetization direction was fixed in second direction Y. External magnetic field Bx in first direction X was decreased from +20 mT to −20 mT in 2 mT steps, and then external magnetic field Bx was increased from −20 mT to +20 mT in 2 mT steps. External magnetic field By in second direction Y and external magnetic field Bz in third direction Z were set to zero.

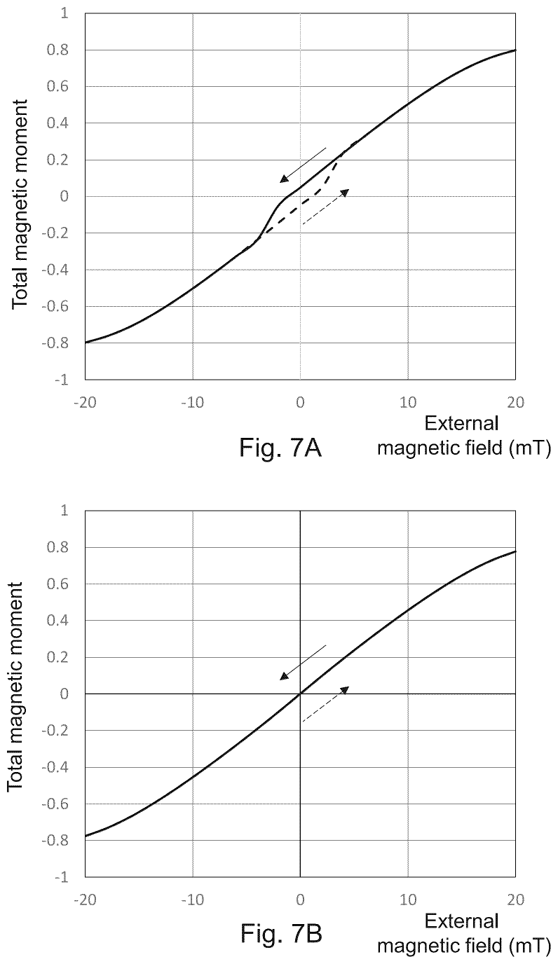

FIG. 7A shows the results of Comparative Example 4, and FIG. 7B shows the results of the working example. The horizontal axis represents magnetic field Bx in first direction X, and the vertical axis represents the value obtained by rescaling the X-component of the total magnetic moment of the magnetization free layer by the saturation magnetic moment of the magnetization free layer, which corresponds to the resistance of the magnetoresistance effect element. In Comparative Example 4, a large hysteresis is observed near a zero magnetic field. This hysteresis is believed to occur because the magnetization direction of magnetization free layer 80 is inclined with respect to second direction Y near the boundaries between magnetization free layer 80 and first and second magnet layers 81 and 82. In the working example, the magnetization direction of magnetization free layer 10 in a zero magnetic field is not inclined with respect to second direction Y near the boundaries between magnetization free layer 10 and first and second magnet layers 21 and 22. The occurrence of hysteresis is believed to have been reduced as a result.

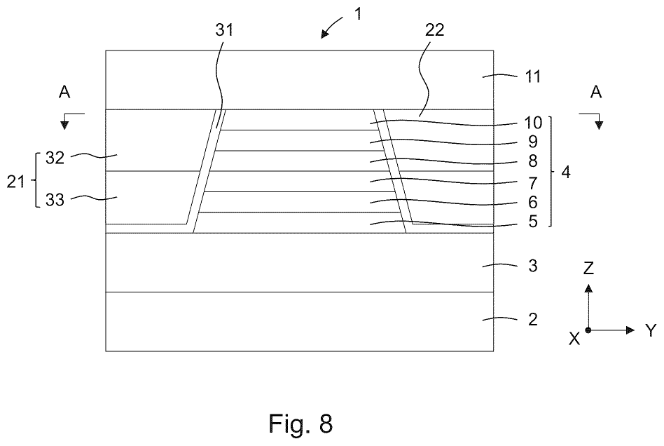

FIG. 8 is a cross-sectional view showing a schematic configuration of magnetoresistance effect element 1 according to another modification of the first embodiment. First and second magnet layers 21 and 22 each have ferromagnetic layer 32 and antiferromagnetic layer 33, and ferromagnetic layer 32 faces magnetization free layer 10 in second direction Y. Ferromagnetic layer 32 is made of CoFe. Antiferromagnetic layer 33 is made of an alloy such as IrMn, Fe—Mn, Ni—Mn, Pt—Mn, or Pd—Pt—Mn, and is strongly exchange-coupled with adjacent ferromagnetic layer 32. Ferromagnetic layer 32 applies a bias magnetic field to magnetization free layer 10 similar to first and second magnet layers 21 and 22 in the first embodiment. Since the magnetization direction of ferromagnetic layer 32 is firmly fixed in second direction Y by antiferromagnetic layer 33, hysteresis in first and second magnet layers 21 and 22 in a zero magnetic field is reduced.

### Second Embodiment

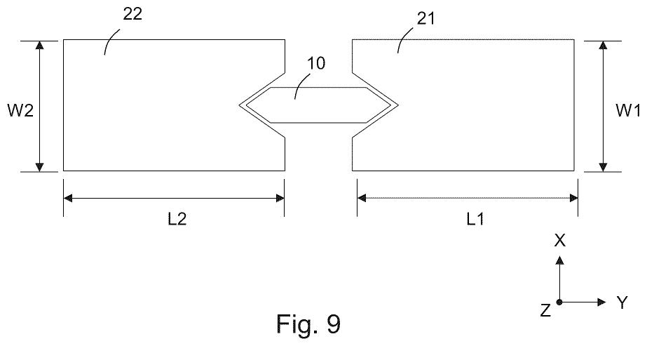

FIG. 9 is a view similar to FIG. 2 of magnetoresistance effect element 1 according to the second embodiment and shows a plan view of the magnetization free layer and the magnet layers. Description of configuration and effects that are similar to those of the first embodiment is here omitted. In this embodiment, dimension L1 in second direction Y of first magnet layer 21 is larger than dimension W1 in first direction X, and dimension L2 in second direction Y of second magnet layer 22 is larger than dimension W2 in first direction X. This change in dimensions allows the direction in which the shape anisotropy effect of first magnet layer 21 and second magnet layer 22 occurs to align with second direction Y. As a result, the bias magnetic field can be stably applied to magnetization free layer 10, and the hysteresis of first and second magnet layers 21 and 22 in a zero magnetic field can be further reduced. Magnetizing first magnet layer 21 and second magnet layer 22 in second direction Y increases the likelihood that the magnetization directions of first magnet layer 21 and second magnet layer 22 will be oriented in second direction Y. Furthermore, when magnetization free layer 10 is elongated in second direction Y, the shape anisotropy of magnetization free layer 10 is also directed in second direction Y, whereby the output of magnetoresistance effect element 1 becomes more stable. Although not shown in the drawings, this embodiment can be combined with the first embodiment and modifications of the first embodiment, as well as with the third and fourth embodiments. In particular, this embodiment can be suitably combined with the modification shown in FIG. 8 because stability due to the shape anisotropy of first and second magnet layers 21 and 22 is important.

### Third Embodiment

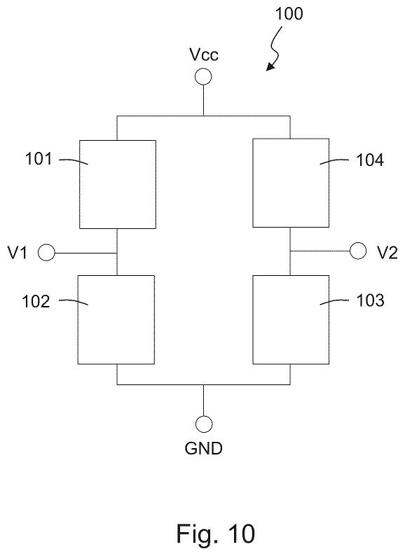

A schematic configuration of magnetic sensor 100 that includes magnetoresistance effect element 1 of the present disclosure will be described with reference to FIG. 10. FIG. 10 shows a schematic circuit diagram of magnetic sensor 100. Magnetic sensor 100 comprises four magnetoresistance effect elements (hereinafter referred to as first to fourth magnetoresistance effect elements 101 to 104) that are connected to each other by a bridge circuit (Wheatstone bridge). All four magnetoresistance effect elements 101 to 104 are magnetoresistance effect element 1 of the first embodiment. The four magnetoresistance effect elements 101 to 104 are divided into two sets, one set being composed of magnetoresistance effect elements 101 and 102 and the other set being composed of magnetoresistance effect elements 103 and 104, and magnetoresistance effect elements 101 and 102 and magnetoresistance effect elements 103 and 104 in each set are connected in series. One end of each set of magnetoresistance elements sets is connected to a power supply voltage Vcc, and the other end of each set of magnetoresistance elements is grounded (GND).

The midpoint voltage V1 between first magnetoresistance effect element 101 and second magnetoresistance effect element 102, and the midpoint voltage V2 between third magnetoresistance effect element 103 and fourth magnetoresistance effect element 104 are extracted. The voltage drops in each of magnetoresistance elements 101 to 104 is approximately proportional to the electric resistance of magnetoresistance elements 101 to 104. Therefore, if the electrical resistances of the first to fourth magnetoresistance effect elements 101 to 104 are R1 to R4, respectively, the midpoint voltage V1 is V1=R2/(R1+R2)×Vcc, and the midpoint voltage V2 is V2=R3/(R3+R4)×Vcc. Detecting the difference V1−V2 between the midpoint voltages V1 and V2 can obtain twice the sensitivity compared to detecting the midpoint voltages V1 and V2. In addition, even if there is an offset between the midpoint voltages V1 and V2, the effect of the offset can be eliminated by detecting the difference. This configuration further reduces the hysteresis of the outputs of magnetoresistance effect elements 101 to 104 that are included in magnetic sensor 100 and thus improves the stability of the output signals.

### Fourth Embodiment

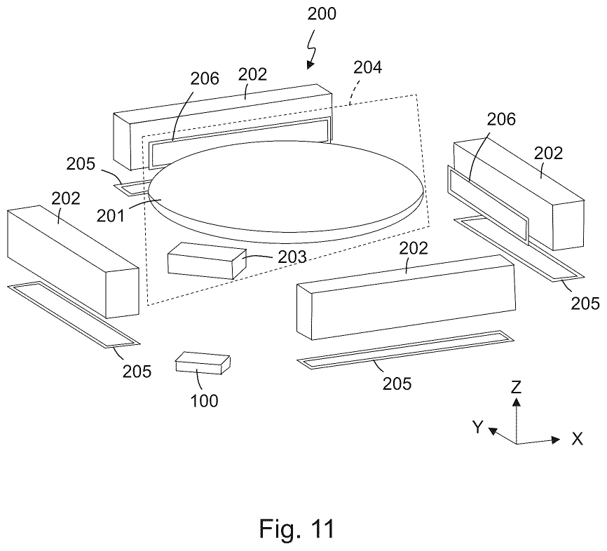

A schematic configuration of camera module 200 that includes magnetic sensor 100 of the present disclosure is next described with reference to FIG. 11. Camera module 200 can perform autofocus and optical image stabilization. Camera module 200 includes lens 201 and four driving magnet layers 202 arranged around lens 201. One first coil 205 is provided below each driving magnet layer 202 in the Z-direction. Lens 201 is held by holding member 204, and a plurality of second coils 206 is placed on holding member 204 so as to surround the periphery of lens 201. Sense magnet layer 203 is placed on holding member 204. Although not shown, another sense magnet layer having a configuration similar to that of sense magnet layer 203 is arranged on the side of lens 201 opposite to sense magnet layer 203. Magnetic sensor 100 is placed on a substrate (not shown) of camera module 200. All elements other than holding member 204 are stationary. Sense magnet layer 203 moves relative to magnetic sensor 100 but drive magnet layers 202 are stationary relative to magnetic sensor 100.

In the case of an autofocus operation, second coils 206 are energized. The Lorentz force causes lens 201 to move in the Z-direction relative to driving magnet layers 202. In the case of an optical image stabilization operation, first coils 205 are energized. The Lorentz force causes lens 201 to move in the X-and/or Y-directions relative to drive magnet layers 202. A composite magnetic field of an external magnetic field generated by drive magnet layers 202 and an external magnetic field generated by sense magnet layer 203 is applied to magnetic sensor 100. Magnetic sensor 100 detects this composite magnetic field, thereby enabling the control of the autofocus operation and the optical image stabilization operation. As described above, magnetic sensor 100 that is included in camera module 200 supplies an output signal having improved stability, and the positional accuracy of camera module 200 is therefore improved.

According to the present disclosure, a magnetoresistance effect element can be provided that is capable of both applying a large bias magnetic field to a magnetization free layer and reducing hysteresis.

### LIST OF REFERENCE NUMERALS

1 magnetoresistance effect element
8 magnetization fixed layer
9 spacer layer
10 magnetization free layer
21, 22 first and second magnet layers
23, 24 first and second recesses
25 innermost portion
26 lateral
32 ferromagnetic layer
33 antiferromagnetic layer
100 magnetic sensor
200 camera module
C1, C2 first and second axes
E1, E2 first and second end portions
S1 to S6 first to sixth sides
X first direction
Y second direction
Z third direction

1. A magnetoresistance effect element comprising:
a magnetization free layer in which magnetization direction is caused to rotate by an external magnetic field;
a magnetization fixed layer in which magnetization direction is fixed in a first direction;
a nonmagnetic spacer layer located between the magnetization free layer and the magnetization fixed layer; and
two magnet layers that sandwich the magnetization free layer in a second direction different from the first direction,
wherein when viewed from a third direction that is perpendicular to the first direction and the second direction, the magnetization free layer includes an end portion that faces either of the two magnet layers, and two linear sides that are connected to the end portion and that extend in different directions from each other, and
wherein the two linear sides are inclined with respect to the second direction.

2. The magnetoresistance effect element according to claim 1, wherein the two linear sides that passes through the end portion extend on both sides of an axis parallel to the second direction.

3. The magnetoresistance effect element according to claim 2, wherein the angle between the two linear sides is equal to or greater than 20 degrees and equal to or less than 120 degrees.

4. The magnetoresistance effect element according to claim 2, wherein the two linear sides are symmetrical with respect to the axis.

5. The magnetoresistance effect element according to claim 1, wherein the lengths of the two magnet layers in the first direction are greater than the length of the magnetization free layer in the first direction.

6. The magnetoresistance effect element according to claim 1, wherein the free magnetization layer is elongated in the second direction.

7. The magnetoresistance effect element according to claim 1, wherein each of the two magnet layers includes a ferromagnetic layer and an antiferromagnetic layer.

8. The magnetoresistance effect element according to claim 1, wherein a length of each of the two magnet layers in the second direction is greater than a length of each of the two magnet layers in the first direction.

9. The magnetoresistance effect element according to claim 1, wherein each of the magnet layers that face the end portion includes a recess for accommodating the two linear sides.

10. The magnetoresistance effect element of claim 9, wherein, when viewed from the third direction, the recess has an innermost portion that faces the end portion in the second direction and two linear laterals that face the two linear sides in the second direction.

11. The magnetoresistance effect element of claim 10, wherein the two linear laterals are longer than the two linear sides.

12. The magnetoresistance effect element according to claim 9, wherein a dimension of an opening of the recess in the first direction is larger than a dimension in the first direction of the magnetization free layer in the opening.

13. A magnetoresistance effect element comprising:
a magnetization free layer in which magnetization direction is caused to rotate by an external magnetic field;
a magnetization fixed layer in which magnetization direction is fixed in a first direction;
a nonmagnetic spacer layer located between the magnetization free layer and the magnetization fixed layer; and
two magnet layers that sandwich the magnetization free layer in a second direction different from the first direction, wherein
when viewed from a third direction that is perpendicular to the first direction and the second direction, the magnetization free layer includes an end portion that faces either of the two magnet layers, each magnet layer includes a recess that faces the end portion, and the recess has an innermost portion and two linear laterals that are connected to the innermost portion.

14. A magnetic sensor comprising the magnetoresistance effect element according to claim 1.

15. A camera module comprising the magnetic sensor according to claim 14.
